(19) United States
(12) Patent Application Publication
(10) Pub. No.: US 2025/0344469 A1
(43) Pub. Date: Nov. 6, 2025

(54) SEMICONDUCTOR STRUCTURES AND FABRICATING METHODS THEREOF

(71) Applicant: YANGTZE MEMORY TECHNOLOGIES CO., LTD., Wuhan (CN)

(72) Inventors: Rui Sang, Wuhan (CN); Meng Wang, Wuhan (CN); Haibo Xie, Wuhan (CN); Zhixiong Zhang, Wuhan (CN); Shen Guo, Wuhan (CN); Sheng Yang, Wuhan (CN)

(21) Appl. No.: 18/660,895

(22) Filed: May 10, 2024

(30) Foreign Application Priority Data
May 6, 2024 (CN) 202410557509.X

(51) Int. Cl. H01L 29/06; H01L 21/02; H01L 21/18; H01L 27/092

(52) U.S. Cl. CPC H10D 62/124; H01L 21/02233; H01L 21/187; H10D 84/856

(57) ABSTRACT

Semiconductor structure and fabricating methods are provided. In some implementations, a disclosed semiconductor structure comprises a lower semiconductor layer, an upper semiconductor layer, and an insulating layer between the lower semiconductor layer and the upper semiconductor layer. A first thickness of the upper semiconductor layer in a first region is greater than a second thickness of the upper semiconductor layer in a second region.

### CROSS-REFERENCE TO RELATED APPLICATIONS

This application claims the benefit of priority to Chinese Application No. 202410557509.X, filed on May 6, 2024, which is incorporated herein by reference in its entirety.

### TECHNICAL FIELD

The present disclosure generally relates to the field of semiconductor technology, and more particularly, to semiconductor devices and fabricating methods thereof.

### BACKGROUND

The Silicon-On-Insulator (SOI) wafer is a cutting-edge semiconductor substrate that offers numerous advantages over traditional bulk silicon substrates, making it a great choice for advanced semiconductor manufacturing processes. SOI technology involves the integration of a thin layer of single-crystal silicon on top of an insulating layer, typically made of silicon dioxide (SiO2), which itself sits atop a bulk silicon substrate. This sandwich-like structure provides several key benefits, such as reduced power consumption, improved performance, enhanced radiation hardness, and mitigation of latch-up effects.

SOI wafers are fabricated using various techniques such as oxygen ion implantation, bond-and-etch-back, and smart-cut processes. These methods enable precise control over the thickness of the silicon layer and the quality of the buried oxide, allowing for customization to meet specific performance requirements. SOI technology represents a significant advancement in semiconductor manufacturing, offering unparalleled performance, reliability, and versatility for a wide range of applications across industries.

### SUMMARY

One aspect of the present disclosure provides a semiconductor structure, comprising: a lower semiconductor layer; an upper semiconductor layer; and an insulating layer between the lower semiconductor layer and the upper semiconductor layer, wherein a first thickness of the upper semiconductor layer in a first region is greater than a second thickness of the upper semiconductor layer in a second region.

In some implementations, the lower semiconductor layer and the upper semiconductor layer comprise silicon; and the insulating layer comprises silicon oxide.

In some implementations, the insulating layer extends in the first region and the second region; and the lower semiconductor layer is separated from the upper semiconductor layer comprising silicon by the insulating layer.

In some implementations, a first upper surface of the upper semiconductor layer in the first region is higher than a second upper surface of the upper semiconductor layer in the second region.

In some implementations, the insulating layer extends in the second region without in the first region; and the lower semiconductor layer is in contact with the upper semiconductor layer comprising silicon in the first region.

In some implementations, the upper semiconductor layer has a flush upper surface.

In some implementations, a thickness of the insulating layer is in a range between 10 nm and 30 nm.

In some implementations, the semiconductor structure further comprises: a first group of transistors having a first operating voltage and formed in the upper semiconductor layer in the first region; and a second group of transistors having a second operating voltage lower than the first operating voltage and formed in the upper semiconductor layer in the second region.

In some implementations, a first material of the upper semiconductor layer is different from a second material of the lower semiconductor layer.

In some implementations, a first material of the upper semiconductor layer is same as a second material of the lower semiconductor layer.

Another aspect of the present disclosure provides a semiconductor structure, comprising: a lower semiconductor layer; an upper semiconductor layer; and an insulating layer between the lower semiconductor layer and the upper semiconductor layer, wherein a first thickness of the insulating layer in a first region is greater than a second thickness of the insulating layer in a second region.

In some implementations, the lower semiconductor layer and the upper semiconductor layer comprise silicon; and the insulating layer comprises silicon oxide.

In some implementations, the upper insulating layer has a flush upper surface; and a first lower surface of the insulating layer in the first region is lower than a second lower surface of the insulating layer in the second region.

In some implementations, the upper semiconductor layer has a flush upper surface; and a first upper surface of the lower semiconductor layer in the first region is lower than a second upper surface of the lower semiconductor layer in the second region.

In some implementations, the semiconductor structure further comprises: a first group of transistors having a first operating voltage and formed in the upper semiconductor layer in the first region; and a second group of transistors having a second operating voltage lower than the first operating voltage and formed in the upper semiconductor layer in the second region.

Another aspect of the present disclosure provides a method of forming a semiconductor structure, comprising: removing a portion of a first semiconductor layer in a second region, such that a first upper surface of the first semiconductor layer in a first region is higher than a second upper surface of the first semiconductor layer in the second region; forming an insulating layer on a second semiconductor layer; bonding the first semiconductor layer to the insulating layer; and thinning the first semiconductor layer, such that a first thickness of the first semiconductor layer in the first region is greater than a second thickness of the first semiconductor layer in the second region.

In some implementations, the semiconductor structure further comprises: bonding the first semiconductor layer to the insulating layer comprises: bonding a flush lower surface of the first semiconductor layer to a flush upper surface of the insulating layer.

Another aspect of the present disclosure provides a method of forming a semiconductor structure, comprising: removing a portion of a second semiconductor layer in a first region, such that a first upper surface of the second semiconductor layer in the first region is lower than a second upper surface of the second semiconductor layer in a second region; forming an insulating layer on the second semiconductor layer, wherein a first thickness of the insulating layer in the first region is greater than a second thickness of the insulating layer in the second region; bonding a first semiconductor layer to the insulating layer; and thinning the first semiconductor layer.

In some implementations, forming the insulating layer comprises: forming the insulating layer to cover the first upper surface and the second upper surface of the second semiconductor layer, wherein a first upper surface of the insulating layer in the first region is lower than a second upper surface of the insulating layer in the second region; and polishing the insulating layer to form a flush upper surface of the insulating layer.

In some implementations, forming the insulating layer comprises: forming the insulating layer to cover the first upper surface and the second upper surface of the second semiconductor layer, wherein a first upper surface of the insulating layer in the first region is lower than a second upper surface of the insulating layer in the second region; removing a portion of the insulating layer in the second region to expose a portion of the second semiconductor layer in the second region; and oxidizing the exposed portion of the second semiconductor layer in the second region to regrow the portion of the insulating layer in the second region, such that the insulating layer has a flush upper surface.

In some implementations, forming the insulating layer on the second semiconductor layer comprises: oxidizing an upper surface of the second semiconductor layer to form the insulating layer

Another aspect of the present disclosure provides a method of forming a semiconductor structure, comprising: forming a mask layer on a second semiconductor layer; removing a portion of the mask layer in a first region to expose a first portion of the second semiconductor layer in the first region; removing a portion of the first portion of the second semiconductor layer in the first region, such that a first upper surface of the second semiconductor layer in the first region is lower than a second upper surface of the second semiconductor layer in a second region cover by the mask layer; oxidizing the first portion of the second semiconductor layer in the first region to form a first portion of an insulating layer in the first region; removing the mask layer in the second region to expose a second portion of the second semiconductor layer in the second region; oxidizing the second portion of the second semiconductor layer in the second region to form a second portion of the insulating layer in the second region, wherein a first thickness of the first portion of the insulating layer in the first region is greater than a second thickness of the second portion of the insulating layer in the second region; bonding a first semiconductor layer to the insulating layer; and thinning the first semiconductor layer.

Another aspect of the present disclosure provides a method of forming a semiconductor structure, comprising: forming an insulating layer on a second semiconductor layer; removing a portion of the insulating layer to expose the second semiconductor layer in a first region; growing a semiconductor material of the second semiconductor layer in the first region, such that the first upper surface of the second semiconductor layer in the first region is flush with an upper surface of the insulating layer; bonding a first semiconductor layer to the upper surface of the insulating layer and the first upper surface of the second semiconductor layer; and thinning the first semiconductor layer.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic diagram of a semiconductor structure, according to some implementations of the present disclosure.

FIG. 2 illustrates a flowchart of a fabricating method for forming a semiconductor structure, according to some implementations of the present disclosure.

FIGS. 3A-3D illustrate schematic side cross-sectional views of portions of a semiconductor structure at certain fabricating stages of the method shown in FIG. 2, according to various implementations of the present disclosure.

FIG. 4 illustrates a schematic diagram of a semiconductor structure, according to some implementations of the present disclosure.

FIG. 5 illustrates a flowchart of a fabricating method for forming a semiconductor structure, according to some implementations of the present disclosure.

FIGS. 6A-6D illustrate schematic side cross-sectional views of portions of a semiconductor structure at certain fabricating stages of the method shown in FIG. 5, according to various implementations of the present disclosure.

FIG. 7 illustrates a flowchart of a fabricating method for forming a semiconductor structure, according to some implementations of the present disclosure.

FIGS. 8A-8D illustrate schematic side cross-sectional views of portions of a semiconductor structure at certain fabricating stages of the method shown in FIG. 7, according to various implementations of the present disclosure.

FIG. 9 illustrates a schematic diagram of a semiconductor structure, according to some implementations of the present disclosure.

FIG. 10 illustrates a flowchart of a fabricating method for forming a semiconductor structure, according to some implementations of the present disclosure.

FIGS. 11A-11D illustrate schematic side cross-sectional views of portions of a semiconductor structure at certain fabricating stages of the method shown in FIG. 10, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features, as described in the present disclosures, can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

As described above, SOI wafers have advantages such as low power consumption, improved performance, enhanced radiation hardness, and mitigation of latch-up effects. First, SOI wafers offer lower power consumption compared to bulk silicon counterparts due to reduced parasitic capacitance and leakage currents. This is particularly advantageous for applications where power efficiency is critical, such as mobile devices and battery-operated systems. Second, by minimizing parasitic capacitance and reducing the impact of substrate coupling, SOI wafers enable faster switching speeds, improved signal integrity, and enhanced overall performance of integrated circuits. This is vital for high-speed digital applications, RF circuits, and mixed-signal designs. Third, the insulating layer in SOI wafers provides inherent isolation between devices, offering improved radiation hardness compared to bulk silicon substrates. This makes SOI technology suitable for aerospace, automotive, and other harsh environment applications where reliability is paramount. Fourth, SOI wafers help mitigate latch-up effects, a common issue in bulk silicon devices, by eliminating the parasitic thyristor structure present in traditional CMOS designs. This enhances the robustness and reliability of SOI-based circuits, particularly in high-voltage and mixed-signal applications.

SOI wafers can be fabricated using various industry-standard techniques such as oxygen ion implantation, bond-and-etch-back, and smart-cut processes. These methods enable precise control over the thickness of the top silicon layer (i.e., the top device layer) and the quality of the buried oxide, allowing for customization to meet specific performance requirements. It is noted that the existing fabricating processes form a fixed thickness of the top device layer. To enhance device performance, there is a concerted effort in the industry to reduce the thickness of the top silicon layer, thereby transitioning from partially depleted to fully depleted devices.

However, in some CMOS designs, the gate oxide thickness for high voltage (HV) transistors/devices is significantly greater than for low voltage (LV) transistors/devices. Forming the HV gate oxide layer consumes a considerable amount of silicon layer thickness, resulting in the top device layer in the HV region becoming too thin. This severely impacts the performance of HV region devices. Conversely, thickening the top device layer to address this issue would degrade the performance of LV region devices. That is, due to variations in gate oxide layer thicknesses, the thickness of the top silicon film differs for different operating voltage regions, making it impossible to simultaneously optimize the performance of HV and LV devices. Consequently, the industry urgently requires a novel SOI wafer solution capable of addressing the issue of excessively thin device layers in HV regions.

To address one or more of the aforementioned issues, the present disclosure introduces an innovative SOI structure with customized thicknesses of the top silicon layer, the insulating layer, and/or the bulk substrate in the HV region and the LV region. Various designs of the present disclosure can address the issue of excessively thin device layers in the HV region while simultaneously optimizing the performance of devices in the LV region, potentially replacing traditional SOI structures. Specifically, the present disclosure involves various designs that effectively resolve the problem of inadequate device layer thickness in the HV region and ensure robust performance and reliability of HV devices, mitigating concerns associated with excessively thin layers. At the same time, the various designs of the present disclosure further facilitate improved performance of LV region devices, as it optimizes capacitance, reduces leakage currents, and enhances overall device efficiency. By implementing the novel SOI structures disclosed herein, manufacturers can achieve a balanced performance across both HV and LV regions, overcoming the limitations of traditional SOI designs. The disclosed innovative SOI structures unlock new possibilities in semiconductor manufacturing, offering enhanced device performance, reliability, and versatility across a diverse range of applications, such as used in dynamic random-access memory (DRAM) fabrication processes, and/or 3D NAND memory fabrication processes.

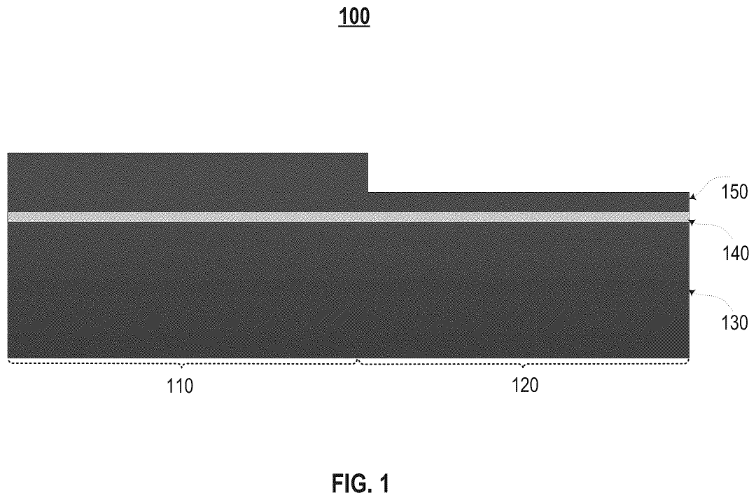

FIG. 1 illustrates a schematic diagram of a semiconductor structure 100, according to some implementations of the present disclosure. As shown in FIG. 1, semiconductor structure 100 can be a Silicon-On-Insulator (SOI) wafer including a lower semiconductor layer 130 (also referred to herein as “second semiconductor layer 130”), an upper semiconductor layer 150 (also referred to herein as “first semiconductor layer 150”), and an insulating layer 140 between the lower semiconductor layer 130 and the upper semiconductor layer 150. Semiconductor structure 100 can include one or more first regions 110 and one or more second regions 120. A first thickness of the upper semiconductor layer 150 in a first region 110 is greater than a second thickness of the upper semiconductor layer 150 in a second region 120.

In some implementations, the lower semiconductor layer 130 can be a bulk substrate providing the foundational support for the insulating layer 140 and the upper semiconductor layer 150. The lower semiconductor layer 130 serves as the base for building semiconductor devices and circuits, providing mechanical support and electrical connectivity. The lower semiconductor layer 130 can include any suitable semiconductor material. In some implementations, silicon is the most common material used for the bulk substrate in SOI wafers. In some other implementations, the lower semiconductor layer 130 can include other materials depending on specific requirements or applications. For example, sapphire substrates offer excellent thermal and electrical insulation properties, making them suitable for high-power and high-frequency applications. Sapphire substrates are also highly transparent in the visible and near-infrared spectrum, making them useful for optoelectronic devices. As another example, silicon germanium (SiGe) substrates combine the properties of both silicon and germanium, offering enhanced performance in terms of mobility, strain engineering, and device integration. SiGe substrates can be used in high-speed and RF applications. As still another example, silicon carbide (SiC) substrates exhibit excellent thermal conductivity, high-temperature stability, and resistance to harsh environments, making them ideal for power electronics, high-temperature sensors, and RF devices. As yet another example, gallium arsenide (GaAs) substrates can be used in optoelectronic and high-frequency devices due to their high electron mobility and direct bandgap, enabling efficient light emission and detection as well as high-speed electronic performance.

In some implementations, the insulating layer 140 of an SOI wafer can include any suitable dielectric materials having electrical isolation, thermal stability, compatibility, and dielectric strength. For example, the insulating layer 140 can typically include silicon dioxide (SiO2), commonly known as oxide. The insulating layer 140 serves as a crucial component in the SOI structure, providing electrical isolation between the lower semiconductor layer 130 (i.e., bulk substrate) and the upper semiconductor layer 150 (a.k.a. active layer). In some implementations, the thickness of the insulating layer 140 can be in a range between 10 nm and 30 nm. It is noted that, silicon dioxide is chosen as the insulator material for several reasons. First, silicon dioxide is an excellent electrical insulator, preventing electrical charge carriers from passing through it. This property ensures that there is minimal electrical interaction between the lower semiconductor layer 130 and the upper semiconductor layer 150, reducing parasitic capacitance and leakage currents. Second, silicon dioxide exhibits high thermal stability, allowing it to withstand the high temperatures encountered during semiconductor fabrication processes, such as oxidation, deposition, and annealing. Third, silicon dioxide is compatible with standard semiconductor processing techniques, making it well-suited for integration into existing fabrication processes. It can be easily deposited, patterned, and etched using techniques such as chemical vapor deposition (CVD) and photolithography. Fourth, silicon dioxide has a high dielectric strength, meaning it can withstand high electric field strengths without breakdown. This property ensures the reliability and integrity of the insulator layer under various operating conditions. Accordingly, the insulating layer 140 in SOI wafers plays a critical role in providing electrical isolation and ensuring the performance, reliability, and manufacturability of semiconductor devices fabricated on the substrate.

In some implementations, the upper semiconductor layer 150 is the active layer in an SOI wafer. In some implementations, the upper semiconductor layer 150 can be a thin layer of single-crystal silicon situated above the insulating layer 140 and separated from the lower semiconductor layer 130. In some implementations, the upper semiconductor layer 150 serves as the primary region where semiconductor devices, such as transistors and diodes, are fabricated. In some implementations, the upper semiconductor layer 150 comprises a high-quality, single-crystal silicon material, which provides excellent electrical properties, including high carrier mobility, low defect density, and uniformity, ensuring optimal device performance and reliability. In some implementations, various suitable semiconductor devices, such as metal-oxide-semiconductor field-effect transistors (MOSFETs), bipolar junction transistors (BJTs), etc., are fabricated directly on the upper semiconductor layer 150 using standard semiconductor processing techniques. These devices can utilize the properties of the single-crystal silicon active layer to achieve desired electrical functionality.

In some other implementations, the upper semiconductor layer 150 can include any other suitable semiconductor materials that can be used as the active layer in semiconductor devices. For example, the upper semiconductor layer 150 can include III-V compound semiconductors, such as gallium arsenide (GaAs), indium phosphide (InP), gallium nitride (GaN), etc. which are widely used in high-frequency and optoelectronic devices. These III-V compound semiconductor materials can offer high electron mobility and bandgap properties suitable for applications like RF amplifiers, lasers, and photodetectors. As another example, the upper semiconductor layer 150 can include II-VI compound semiconductors, such as zinc oxide (ZnO), cadmium sulfide (CdS), etc., which are used in various electronic and optoelectronic devices due to their unique electrical and optical properties. These II-VI compound semiconductor materials can be used to form sensors, light-emitting diodes (LEDs), and solar cells. As still another example, the upper semiconductor layer 150 can include organic semiconductors, such as polymers, small molecules, etc., which are used for flexible electronics, organic light-emitting diodes (OLEDs), and organic photovoltaics (OPVs). These organic semiconductor materials can offer advantages such as low-cost fabrication, flexibility, and large-area coverage. As still another example, the upper semiconductor layer 150 can include Perovskite semiconductor materials, such as methylammonium lead iodide (MAPbI3), which can be used for solar cells, LEDs, and photodetectors due to their excellent optoelectronic properties and low-cost fabrication processes.

In some implementations, various semiconductor devices requiring a wide range of voltages to be supplied may be formed on the same SOI wafer. For example, a memory device, such as a 3D NAND flash memory device, a 3D ferroelectric memory device, a 3D DRAM device, etc., can include multiple voltage sources, each being configured to provide a voltage at a respective level, such as a low voltage (LV) level (e.g., lower than about 10 V), or a high voltage (HV) level (e.g., high than about 10 V) to respective HV or LV semiconductor devices located on different regions of the SOI wafer. As such, the semiconductor structure 100 can include one or more first regions 110 used as HV circuit regions, and one or more second regions 120 used as LV circuit regions. In one specific example when the SOI wafer is used for forming peripheral circuits of a NAND memory device, the one or more first regions 110 (i.e., HV circuit regions) can include one or more of word line driving circuits, bit line driving circuits, etc., while the one or more second regions 120 (i.e., LV circuit regions) can include one or more of page buffer circuits, logic circuits, input/output (I/O) circuits, etc. That is, a first group of transistors (not shown) having a first operating voltage can be formed in the upper semiconductor layer 150 in the first region 110, and a second group of transistors (not shown) having a second operating voltage lower than the first operating voltage can be formed in the upper semiconductor layer 150 in the second region 120.

In some implementations, the upper semiconductor layer 150 (i.e., active layer) can be tailored to meet the requirements of specific applications by adjusting parameters such as doping concentration, crystal orientation, and strain engineering. This customization allows for the optimization of device performance, power efficiency, and integration density. In some implementations, the thickness of the upper semiconductor layer 150 (i.e., active layer) can be precisely controlled during the wafer fabrication process, typically ranging from a few nanometers to several micrometers. This controlled thickness allows for the customization of device characteristics and performance. Specifically, as shown in FIG. 1, a first thickness of the upper semiconductor layer 150 in a first region 110 (i.e., HV region) is greater than a second thickness of the upper semiconductor layer 150 in a second region 120 (i.e., LV region). That is, a first upper surface of the upper semiconductor layer 150 in the first region 110 is higher than a second upper surface of the upper semiconductor layer 150 in the second region 120. In some implementations, the thickness difference of the upper semiconductor layer 150 between the HV and LV regions can be formed by photolithography-etching process on the upper semiconductor layer 150 before bonding the upper semiconductor layer 150 to the insulating layer 140, and an intelligent cutting process on the upper semiconductor layer 150 before bonding the upper semiconductor layer 150 to the insulating layer 140.

In contrast to traditional SOI wafer, the disclosed semiconductor structure 100 substantially thickens the upper semiconductor layer 150 (i.e., active layer) in the HV regions, effectively addressing the issue of thin device layer in the HV regions. This enhancement ensures robust performance and reliability of HV devices by providing adequate thickness. Further, the disclosed semiconductor structure 100 ensures that the upper semiconductor layer 150 (i.e., active layer) remains relatively thin in the LV regions, thereby enhancing the performance of LV devices. This optimization allows for improved capacitance, reduced leakage currents, and overall enhanced efficiency of LV devices while maintaining compatibility with low-voltage operation. By implementing this enhanced approach, the disclosed semiconductor structure 100 can achieve a balanced performance across both HV and LV regions, overcoming the limitations of traditional processes. This innovation promises to advance semiconductor manufacturing, offering improved device performance, reliability, and versatility across various applications. It is noted that, although FIG. 1 shows only two types of regions corresponding to two levels of voltages (i.e., HV and LV), three or more types of regions corresponding to multiple levels of voltages (e.g., HHV, HV, LV, and LLV, etc.) can be applied based on the spirit of the present disclosure.

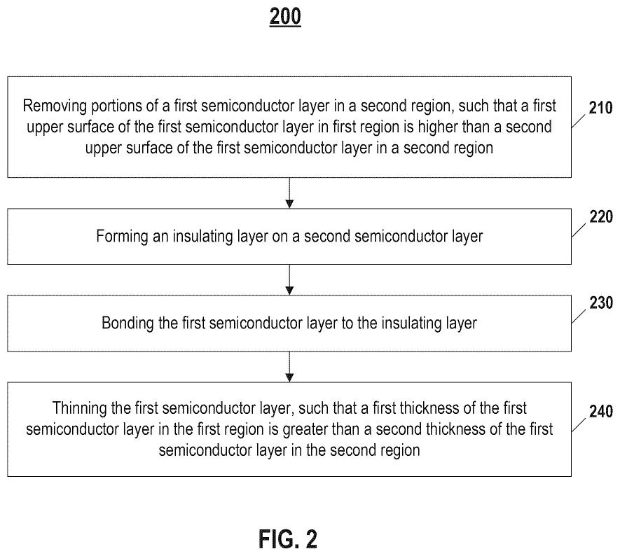

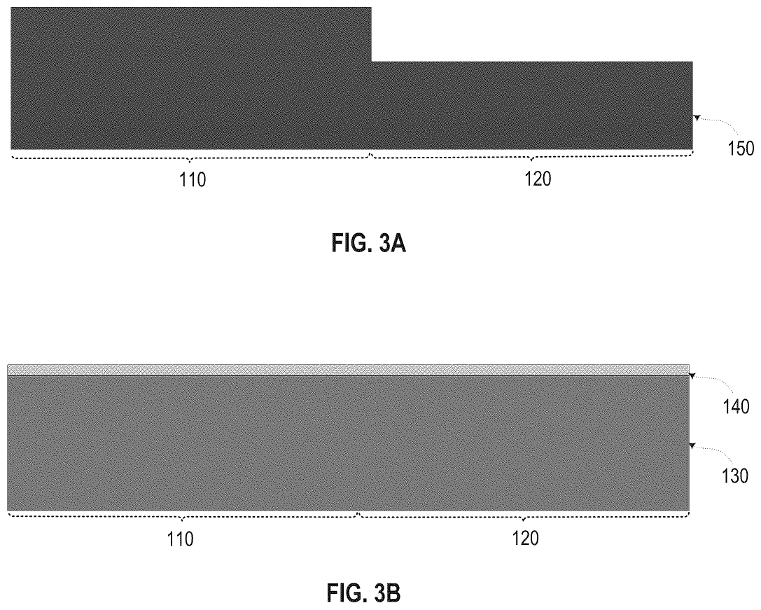

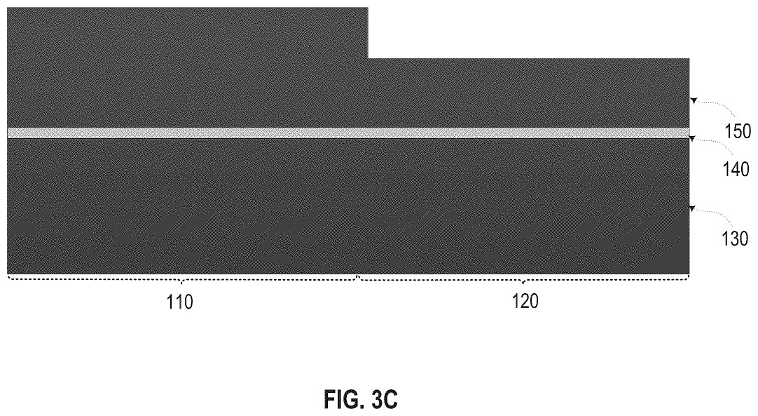

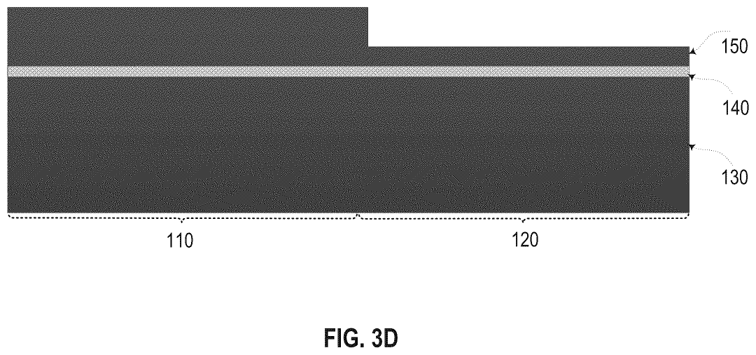

Referring to FIG. 2, a flowchart of a fabricating method 200 for forming the semiconductor structure 100 is illustrated, according to some implementations of the present disclosure. FIGS. 3A-3D illustrate schematic side cross-sectional views of portions of the semiconductor structure at certain fabricating stages of method 200 shown in FIG. 2, according to various implementations of the present disclosure. It is understood that the operations shown in method 200 are not exhaustive and that other operations can be performed as well before, after, or between any of the illustrated operations. Further, some of the operations may be performed simultaneously, or in a different order than shown in FIG. 2.

As shown in FIG. 2, method 200 can start at operation 210, in which portions of a first semiconductor layer in a second region can be removed, such that a first upper surface of the first semiconductor layer in first region is higher than a second upper surface of the first semiconductor layer in a second region. FIG. 3A illustrates a schematic side cross-sectional view of the first semiconductor layer after operation 210 of method 200.

As shown in FIG. 3A, the first semiconductor layer 150 can be a semiconductor substrate, which can include silicon (e.g., single crystalline silicon, c-Si), or any other suitable semiconductor materials described above that can be used as the active layer in semiconductor devices. In such implementations, portions of the first semiconductor layer 150 in the second regions 120 can be removed, such that first upper surfaces of the first semiconductor layer 150 in first regions 110 are higher than second upper surfaces of the first semiconductor layer 150 in the second regions 120.

In some implementations, the thickness difference of the first semiconductor layer 150 in the first regions 110 and the second regions 120 can be formed by a patterning process (e.g., photoetching, dry etching, wet etching, cleaning, chemical mechanical polishing (CMP), etc.,) to remove portions of the first semiconductor layer 150 in the second regions 120. In some specific implementations, a photolithography-etching process, including substrate preparation, photoresist application, exposure, development, etching, resist stripping, and post-processing, can be performed to precisely pattern the first semiconductor layer 150.

Referring back to FIG. 2, method 200 can proceed to operation 220, in which an insulating layer can be formed on a second semiconductor layer. FIG. 3B illustrates a schematic side cross-sectional view of the insulating layer and the second semiconductor layer after operation 220 of method 200.

As shown in FIG. 3B, an insulating layer 140 can be formed on a second semiconductor layer 130, and can extend in both first regions 110 and the second regions 120. In some implementations, the fabricating process of forming the insulating layer 140 on the second semiconductor layer 130 can include a substrate preparation process to prepare the semiconductor layer 130. The process begins with preparing a high-quality silicon wafer, known as the bulk substrate. The substrate is cleaned thoroughly to remove any contaminants and ensure a pristine surface for subsequent processing steps. In some implementations, the insulating layer 140 can be deposited on the second semiconductor layer 130 by performing a series of thin film deposition processes (e.g., chemical vapor deposition (CVD), plasma-enhanced chemical vapor deposition (PECVD), physical vapor deposition (PVD), atomic layer deposition (ALD), etc.) and patterning processes (e.g., photoetching, dry etching, wet etching, cleaning, chemical mechanical polishing (CMP), etc.).

In some other implementations, insulating layer 140 can be formed on the second semiconductor layer 130 by using a thermal oxidation process. For example, the silicon substrate is exposed to high temperatures in the presence of oxygen or water vapor. During oxidation, oxygen atoms diffuse into the silicon substrate and react with silicon atoms to form a layer of silicon dioxide (SiO2) on the surface. This process can be performed in a high-temperature furnace or using rapid thermal processing (RTP) techniques. Further, forming the insulating layer 140 can further include an oxide thickness control process. In some implementations, the thickness of the silicon dioxide layer can be precisely controlled by adjusting parameters such as temperature, time, and oxygen concentration during the oxidation process, thereby allowing for the thickness customization of the insulating layer 140 to meet specific design requirements. Finally, forming the insulating layer 140 can further include a planarization process, such as chemical-mechanical polishing (CMP), to achieve a flat and smooth surface topography.

Referring back to FIG. 2, method 200 can proceed to operation 230, in which the first semiconductor layer can be bonded to the insulating layer. FIG. 3C illustrates a schematic side cross-sectional view of the bonded semiconductor structure after operation 230 of method 200.

As shown in FIG. 3C, a flush lower surface of the first semiconductor layer 150 can be bonded to a flush upper surface of the insulating layer 140. In some implementations, bonding the first semiconductor layer 150 to the insulating layer 140 can include a series of fabricating processes including surface preparation, surface activation, alignment and contact, bonding, annealing, and post-bonding treatment. In the surface preparation, both the first semiconductor layer 150 (i.e., active layer) and the insulating layer 140 are prepared by cleaning and ensuring their surfaces are free from contaminants, thereby promoting strong adhesion during bonding. Then, a surface activation process may be employed to enhance bonding between the first semiconductor layer 150 (i.e., active layer) and the insulating layer 140. For example, plasma treatment or chemical functionalization can be used to modify the surface chemistry and promote bonding. Next, the first semiconductor layer 150 (i.e., active layer) and the insulating layer 140 can be brought into close contact with each other while ensuring proper alignment of their respective surfaces to ensure uniformity and integrity across the wafer.

It is noted that, various bonding methods can be used to join the first semiconductor layer 150 (i.e., active layer) and the insulating layer 140, including direct bonding, anodic bonding, and wafer bonding with an intermediate layer. In the direct bonding, the two surfaces of the first semiconductor layer 150 (i.e., active layer) and the insulating layer 140 are brought into contact under controlled conditions, such as temperature and pressure, to promote molecular adhesion. The bonded interface forms a strong and permanent bond without the need for additional bonding agents. In the anodic bonding, an electric field can be applied across the first semiconductor layer 150 (i.e., active layer) and the insulating layer 140 while they are in contact, thereby creating a strong bond by inducing ionic migration and electrostatic attraction at the interface. In some implementations, an intermediate layer (not shown) may be introduced between the first semiconductor layer 150 (i.e., active layer) and the insulating layer 140 to facilitate bonding. The intermediate layer can be a thin oxide or nitride layer that enhances bonding and promotes adhesion.

It is further noted that, the bonding process is typically carried out under controlled conditions, including temperature, pressure, and duration, optimized to achieve a strong and reliable bond while minimizing defects and stress in the bonded structure. After bonding, the bonded structure as shown in FIG. 3C may undergo annealing or other post-bonding treatments to further improve the bond strength, remove defects, and relieve stress in the bonded structure. In addition, various inspection and testing techniques, such as microscopy, bond strength measurements, and defect analysis, can be employed to ensure the quality and integrity of the bonded structure before proceeding to subsequent processing steps.

Referring back to FIG. 2, method 200 can proceed to operation 240, in which the first semiconductor layer can be thinned, such that a first thickness of the first semiconductor layer in the first region is greater than a second thickness of the first semiconductor layer in the second region. FIG. 3D illustrates a schematic side cross-sectional view of the bonded semiconductor structure after operation 240 of method 200.

In some implementations as shown in FIG. 3D, after bonding the first semiconductor layer 150 (i.e., active layer) to the insulating layer 140, the first semiconductor layer 150 (i.e., active layer) can be thinned to achieve the desired thicknesses the first semiconductor layer 150 in the first regions 110 and in the second regions 120. In some implementations, the first semiconductor layer 150 can be thinned by performing a mechanical grinding process followed by an optional chemical-mechanical polishing (CMP) process.

In some implementations, the bonded structure can undergo a mechanical grinding process to remove excess portions of the first semiconductor layer 150 (i.e., active layer), thereby thinning the active layer. In some implementations, the mechanical grinding process can be performed using any suitable precision grinding equipment that removes silicon material in a controlled manner to reduce the thicknesses of the first semiconductor layer 150 (i.e., active layer) in the first regions 110 and the second regions 120 to predefined target thicknesses, respectively. In some implementations, the mechanical grinding process can be performed gradually, with frequent measurements to monitor the thicknesses of the first semiconductor layer 150 (i.e., active layer) in the first regions 110 and the second regions 120 and ensure uniform thinning across the wafer.

In some implementations, following the mechanical grinding process, the bonded structure can undergo a CMP process to further thin and smoothen the first semiconductor layer 150 (i.e., active layer). It is noted that, the CMP process can include simultaneous application of chemical etchants and mechanical abrasion to remove material from the wafer surface. For example, during the CMP process, a slurry containing abrasive particles and chemical etchants can be applied to the surface of the first semiconductor layer 150 (i.e., active layer), and one or more polishing pads can be pressed against certain regions of the first semiconductor layer 150 (i.e., active layer), creating a chemical and mechanical polishing action. The combination of chemical reactions and mechanical abrasion helps to achieve precise control over the thinning process and ensures a smooth, uniform surface finish. The CMP process can continue until the first semiconductor layer 150 (i.e., active layer) reaches the desired final thicknesses in the first regions 110 and the second regions 120, as determined by metrology measurements and quality control criteria.

It is noted that, throughout the thinning process, the thicknesses of the first semiconductor layer 150 (i.e., active layer) in the first regions 110 and the second regions 120 can be monitored using metrology techniques such as optical interferometry, ellipsometry, or atomic force microscopy (AFM). Further, quality control measures can be implemented to ensure that the thinning process meets the specified requirements for thickness uniformity, surface roughness, and defect density. Any deviations from the target thicknesses of the first semiconductor layer 150 (i.e., active layer) in the first regions 110 and the second regions 120 or quality standards can be addressed through adjustments to the thinning parameters or process conditions. Once the first semiconductor layer 150 (i.e., active layer) reaches the desired thicknesses in the first regions 110 and the second regions 120, the bonded structure can undergo final cleaning to remove any residues or contaminants from the thinning process.

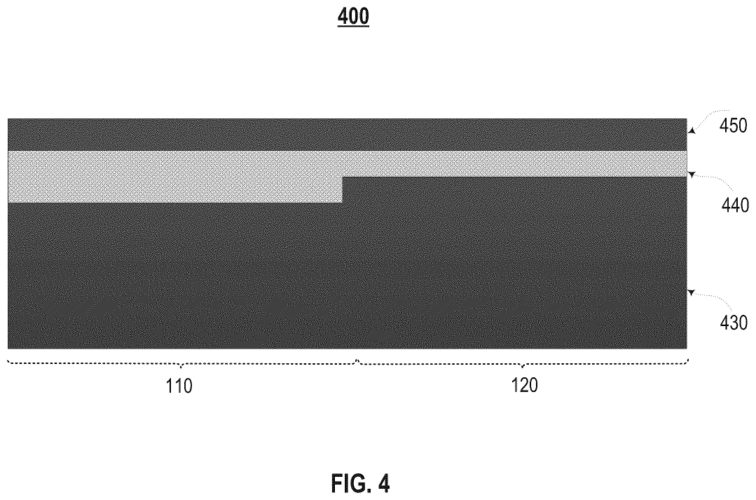

FIG. 4 illustrates a schematic diagram of a semiconductor structure 400, according to some implementations of the present disclosure. As shown in FIG. 4, semiconductor structure 400 can be a Silicon-On-Insulator (SOI) wafer including a lower semiconductor layer 430 (also referred to herein as “second semiconductor layer 430”), an upper semiconductor layer 450 (also referred to herein as “first semiconductor layer 450”), and an insulating layer 440 between the lower semiconductor layer 430 and the upper semiconductor layer 450. Semiconductor structure 400 can include one or more first regions 110 and one or more second regions 120. A first thickness of the insulating layer 440 in a first region 110 is greater than a second thickness of the insulating layer 440 in a second region 120.

It is noted that, compared to the semiconductor structure 100 as shown in FIG. 1, the same properties of the lower semiconductor layer 430, the insulating layer 440, and the upper semiconductor layer 450 in semiconductor structure 400 can be referred to the descriptions above about the lower semiconductor layer 130, the insulating layer 140, and the upper semiconductor layer 150, which are not repeated herein. Only the different portions of the lower semiconductor layer 430, the insulating layer 440, and the upper semiconductor layer 450 in semiconductor structure 400 are described in the following.

As shown in FIG. 4, the lower semiconductor layer 430 can have a non-flush upper surface. In some implementations, first upper surfaces of the lower semiconductor layer 430 in the first regions 110 (i.e., HV circuit regions) can be lower than second upper surfaces of the lower semiconductor layer 430 in the second regions 120 (i.e., LV circuit regions). That is, a first thickness of the lower semiconductor layer 430 in a first region 110 (i.e., HV region) is less than a second thickness of the lower semiconductor layer 430 in a second region 120 (i.e., LV region). Further, the insulating layer 440 can have a non-flush lower surface. In some implementations, first lower surfaces of the insulating layer 440 in the first regions 110 (i.e., HV circuit regions) can be lower than second lower surfaces of the insulating layer 440 in the second regions 120 (i.e., LV circuit regions). That is, a first thickness of the insulating layer 440 in a first region 110 (i.e., HV region) is greater than a second thickness of the insulating layer 440 in a second region 120 (i.e., LV region). The upper surface of the insulating layer 440 is a flush surface, and the first semiconductor layer 450 above the insulating layer 440 has a uniform thickness and flush upper and lower surfaces.

In contrast to traditional SOI wafer, the disclosed semiconductor structure 400 substantially thickens the insulating layer 440 in the HV regions, effectively addressing the leakage issue in the HV regions. Further, the enhancement of the disclosed semiconductor structure 400 uses multiple photolithography steps to create varying back gate oxide thicknesses in different voltage regions such as HV, LV, and LLV, thereby enhancing the device performance. This optimization allows for improved capacitance, reduced leakage currents, and overall enhanced efficiency of LV devices while maintaining compatibility with low-voltage operation. By implementing these improvements on the disclosed semiconductor structure 400, semiconductor structure 400 can have optimized back gate oxide thicknesses tailored to different voltage requirements, achieving a balanced performance across both HV and LV regions, overcoming the limitations of traditional processes, resulting in enhanced device performance, reduced leakage issues, and improved reliability across various voltage regions. It is noted that, although FIG. 4 shows only two types of regions corresponding to two levels of voltages (i.e., HV and LV), three or more types of regions corresponding to multiple levels of voltages (e.g., HHV, HV, LV, and LLV, etc.) can be applied based on the spirit of the present disclosure.

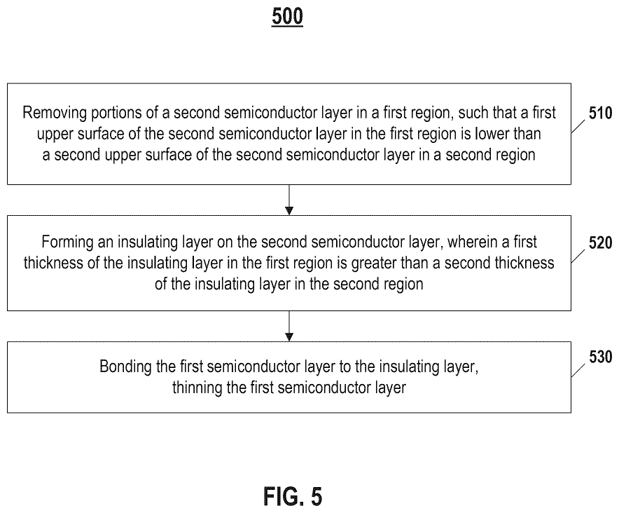

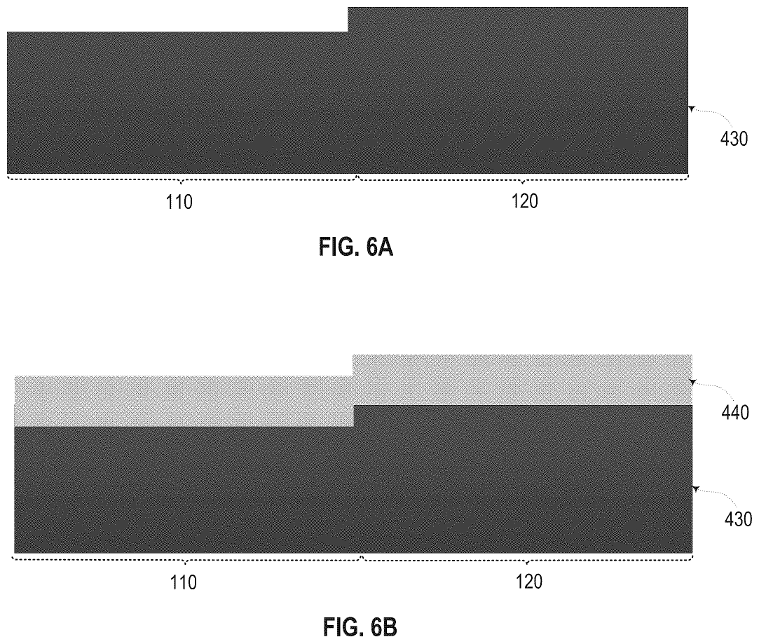

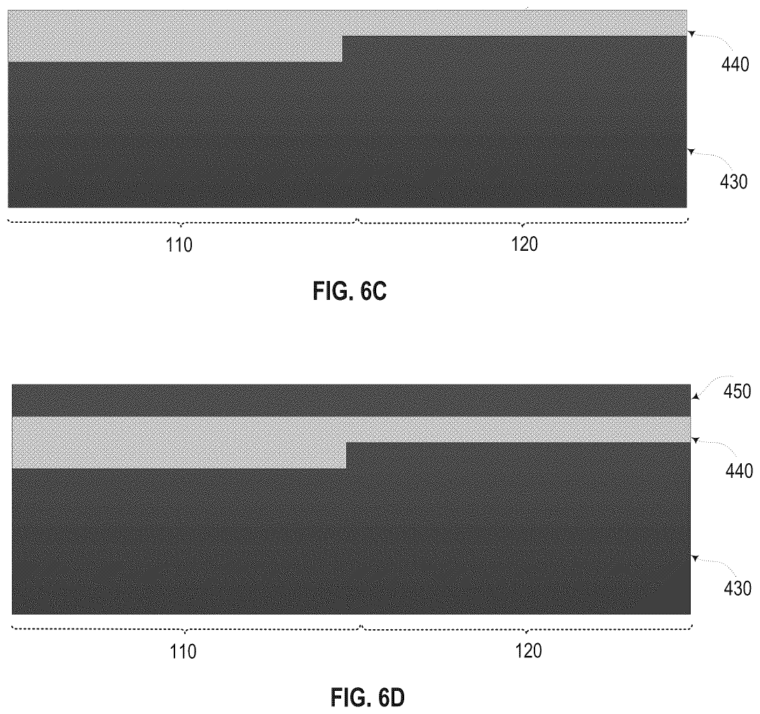

Referring to FIG. 5, a flowchart of a fabricating method 500 for forming the semiconductor structure 400 is illustrated, according to some implementations of the present disclosure. FIGS. 6A-6D illustrate schematic side cross-sectional views of portions of the semiconductor structure at certain fabricating stages of the method 500 shown in FIG. 5, according to various implementations of the present disclosure. It is understood that the operations shown in method 500 are not exhaustive and that other operations can be performed as well before, after, or between any of the illustrated operations. Further, some of the operations may be performed simultaneously, or in a different order than shown in FIG. 5. It is noted that, some detailed fabricating processes can be referred to the description of method 200 above in connection with FIG. 2, which are not repeated herein, and only the different portions are described in the following.

As shown in FIG. 5, method 500 can start at operation 510, in which portions of a second semiconductor layer in a first region can be removed, such that a first upper surface of the second semiconductor layer in the first region is lower than a second upper surface of the second semiconductor layer in a second region. FIG. 6A illustrates a schematic side cross-sectional view of the first semiconductor layer after operation 510 of method 500.

As shown in FIG. 6A, portions of the second semiconductor layer 430 in the first regions 110 can be removed, such that first upper surfaces of the second semiconductor layer 430 in first regions 110 are lower than second upper surfaces of the second semiconductor layer 430 in the second regions 120. In some implementations, the thickness difference of the second semiconductor layer 430 in the first regions 110 and the second regions 120 can be formed by a patterning process (e.g., photoetching, dry etching, wet etching, cleaning, chemical mechanical polishing (CMP), etc.,) to remove portions of the second semiconductor layer 430 in the first regions 110. In some specific implementations, a photolithography-etching process, including substrate preparation, photoresist application, exposure, development, etching, resist stripping, and post-processing, can be performed to precisely pattern the second semiconductor layer 430.

Referring back to FIG. 5, method 500 can proceed to operation 520, in which an insulating layer can be formed on the second semiconductor layer, wherein a first thickness of the insulating layer in the first region is greater than a second thickness of the insulating layer in the second region. FIGS. 6B and 6C each illustrates a schematic side cross-sectional view of the insulating layer and the second semiconductor layer at a certain stage of operation 520 of method 500.

As shown in FIG. 6B, an insulating layer 440 can be formed on the second semiconductor layer 430, and can extend in both first regions 110 and the second regions 120. In some implementations, the insulating layer 440 can be deposited on the second semiconductor layer 430 by performing any suitable thin film deposition process (e.g., CVD, PECVD, PVD, ALD, etc.) In some other implementations, the insulating layer 440 can be formed by performing a thermal oxidation process on the upper surface of the second semiconductor layer 430. Since the second semiconductor layer 430 has a non-flush upper surface, the formed insulating layer 440 also has a non-flush upper surface. As shown in FIG. 6C, in some implementations, a CMP process can be performed on the insulating layer 440 to form a flush upper surface of the insulating layer 440. As such, the first thickness of the insulating layer 440 in the first regions 110 can be greater than a second thickness of the insulating layer 440 in the second regions 120. In some other implementations not shown in the figures, portions of the insulating layer 440 in the second regions 120 can be removed by using a photolithography wet etching process, and a followed oxidization process can be performed to reform the insulating layer 440, which has a flush upper surface.

Referring back to FIG. 5, method 500 can proceed to operation 530, in which a first semiconductor layer can be bonded to the insulating layer, and the first semiconductor layer can be thinned. FIG. 6D illustrates a schematic side cross-sectional view of the bonded semiconductor structure after operation 530 of method 500.

As shown in FIG. 6D, the first semiconductor layer 450 (i.e., active layer) can be bonded to the insulating layer 440 by any suitable bonding method described above. After bonding the first semiconductor layer 450 (i.e., active layer) to the insulating layer 440, the first semiconductor layer 450 (i.e., active layer) can be thinned to achieve the desired thickness. In some implementations, the first semiconductor layer 450 can be thinned by performing a CMP process.

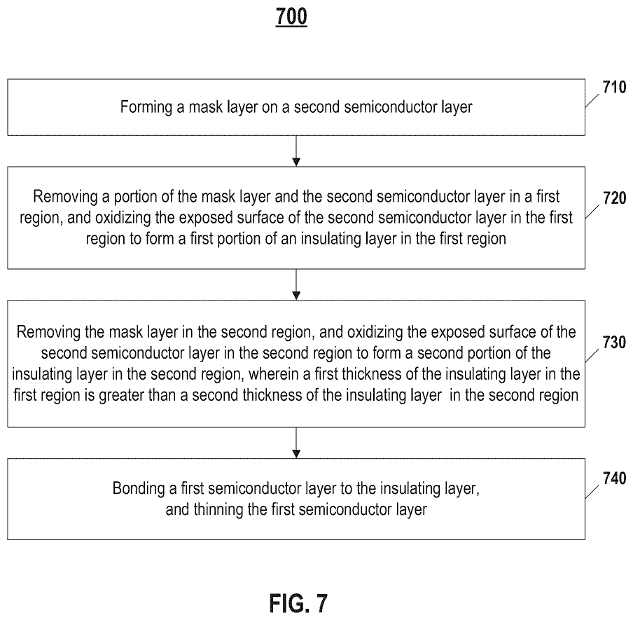

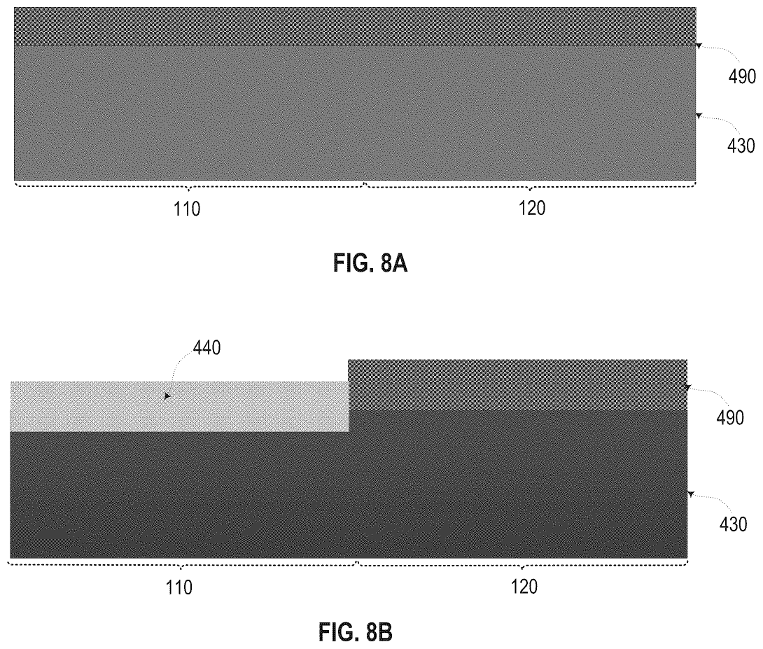

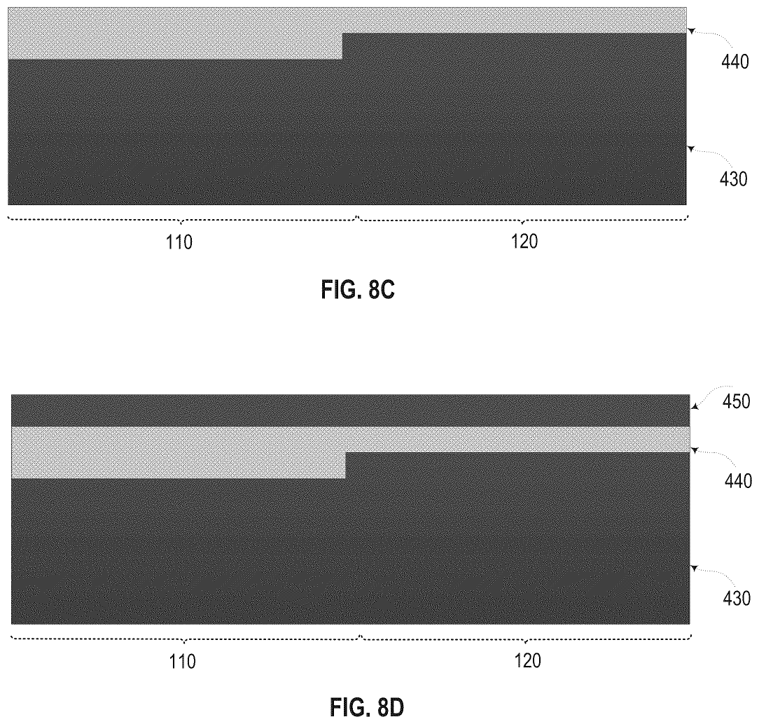

Referring to FIG. 7, a flowchart of another fabricating method 700 for forming the semiconductor structure 400 is illustrated, according to some implementations of the present disclosure. FIGS. 8A-8D illustrate schematic side cross-sectional views of portions of the semiconductor structure at certain fabricating stages of the method 700 shown in FIG. 7, according to various implementations of the present disclosure. It is understood that the operations shown in method 700 are not exhaustive and that other operations can be performed as well before, after, or between any of the illustrated operations. Further, some of the operations may be performed simultaneously, or in a different order than shown in FIG. 7. It is noted that, some detailed fabricating processes can be referred to the description of method 200 above in connection with FIG. 2, which are not repeated herein, and only the different portions are described in the following.

As shown in FIG. 7, method 700 can start at operation 710, in which a mask layer can be formed on a second semiconductor layer. FIG. 8A illustrates a schematic side cross-sectional view of the mask layer 490 formed on the second semiconductor layer 430 after operation 710 of method 700. In some implementations, the mask layer 490 can be a hard mask layer, such as a SiN layer.

Referring to FIG. 7 and FIG. 8B, method 700 can proceed to operation 720, in which a portion of the mask layer 490 in a first region 110 can be removed to expose a first portion of the second semiconductor layer 430 in the first region 110, a portion of the second semiconductor layer 430 in the first region 110 can be removed, such that a first upper surface of the second semiconductor layer 430 in the first region 110 is lower than a second upper surface of the second semiconductor layer 430 in a second region 120 cover by the remaining portion of the mask layer 490, and the first upper surface of the second semiconductor layer 430 in the first region 110 can be oxidized to form a first portion of an insulating layer 440 in the first region 110.

Referring to FIG. 7 and FIG. 8C, method 700 can proceed to operation 730, in which the mask layer 490 in the second region 120 can be removed to expose the second upper surface of the second semiconductor layer 430 in the second region 120, the second upper surface of the second semiconductor layer 430 in the second region 120 can then be oxidized to form a second portion of the insulating layer 440 in the second region 120. A first thickness of the insulating layer 440 in the first region 110 is greater than a second thickness of the insulating layer 440 in the second region 120.

Referring to FIG. 7 and FIG. 8D, method 700 can proceed to operation 740, in which a first semiconductor layer 450 can be bonded to the insulating layer 440, and the first semiconductor layer 450 can be thinned. FIG. 8D illustrates a schematic side cross-sectional view of the bonded semiconductor structure after operation 740 of method 700.

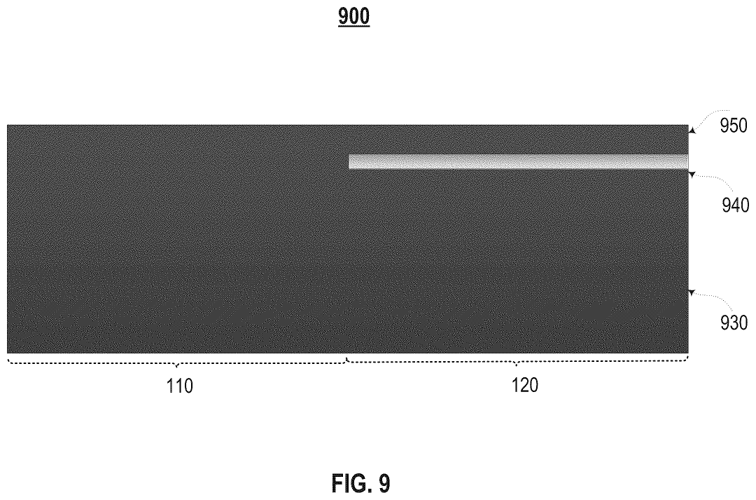

FIG. 9 illustrates a schematic diagram of a semiconductor structure 900, according to some implementations of the present disclosure. As shown in FIG. 9, semiconductor structure 900 can be a Silicon-On-Insulator (SOI) wafer including a lower semiconductor layer 930 (also referred to herein as “second semiconductor layer 930”) and an upper semiconductor layer 950 (also referred to herein as “first semiconductor layer 950”). The lower semiconductor layer 930 and the upper semiconductor layer 950 can be in direct contact with each other in the first regions 110 (i.e., HV regions). An insulating layer 940 can be located between the lower semiconductor layer 930 and the upper semiconductor layer 950 in the second regions 120 (i.e., LV regions).

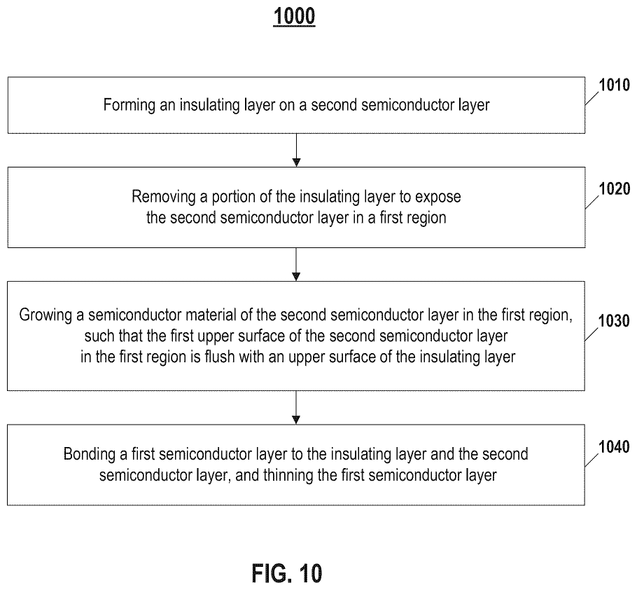

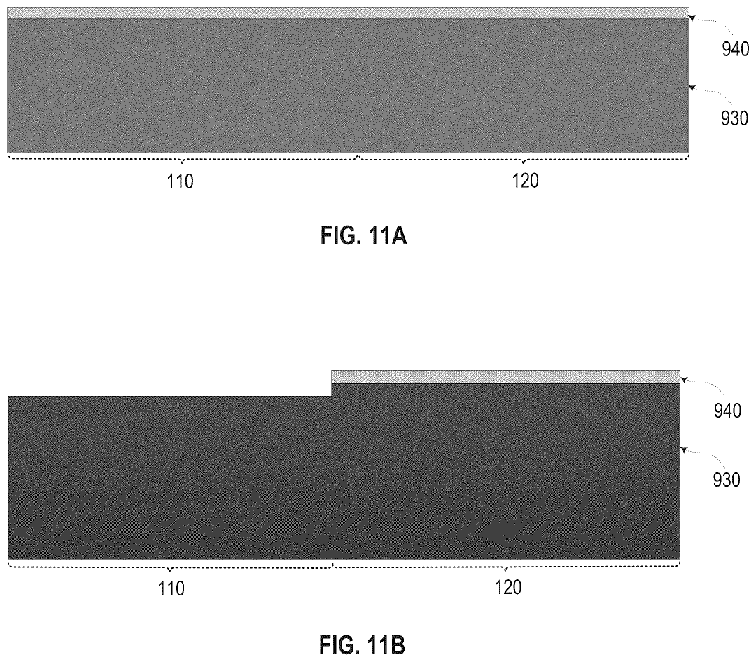

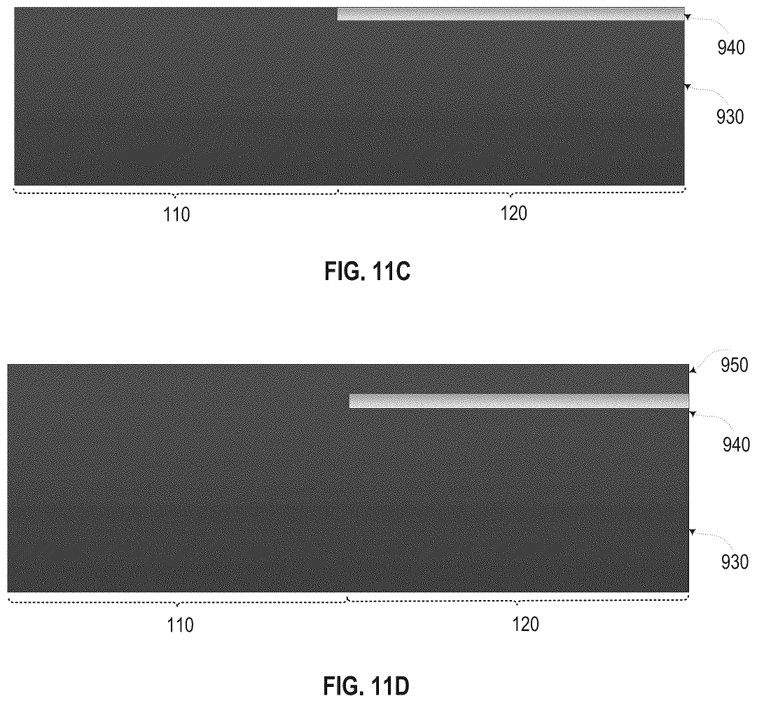

Referring to FIG. 10, a flowchart of a fabricating method 1000 for forming the semiconductor structure 900 is illustrated, according to some implementations of the present disclosure. FIGS. 11A-11D illustrate schematic side cross-sectional views of portions of the semiconductor structure at certain fabricating stages of the method 1000 shown in FIG. 10, according to various implementations of the present disclosure. It is understood that the operations shown in method 1000 are not exhaustive and that other operations can be performed as well before, after, or between any of the illustrated operations. Further, some of the operations may be performed simultaneously, or in a different order than shown in FIG. 10. It is noted that, some detailed fabricating processes can be referred to the description of method 200 above in connection with FIG. 2, which are not repeated herein, and only the different portions are described in the following.

As shown in FIG. 10 and FIG. 11A, method 1000 can start at operation 1010, in which an insulating layer 940 can be formed on a second semiconductor layer 930, and can extend in both first regions 110 and the second regions 120. In some implementations, the insulating layer 940 can be deposited on the second semiconductor layer 930 by performing any suitable thin film deposition process (e.g., CVD, PECVD, PVD, ALD, etc.) In some other implementations, the insulating layer 940 can be formed by performing a thermal oxidation process on the upper surface of the second semiconductor layer 930.

Referring to FIG. 10 and FIG. 11B, method 1000 can proceed to operation 1020, in which a portion of the insulating layer 940 in a first region 110 can be removed to expose the second semiconductor layer 930 in the first region 110. In some implementations, the portion of the insulating layer 940 in the first region 110 can be removed by a patterning process (e.g., photoetching, dry etching, wet etching, cleaning, etc.). In some specific implementations, a photolithography-etching process, including substrate preparation, photoresist application, exposure, development, etching, resist stripping, and post-processing, can be performed to precisely pattern the insulating layer 940. It is noted that, in some implementations, a portion of the second semiconductor layer 930 can be removed as well during the process of removing the portion of the insulating layer 940 in the first region 110, such that a first upper surface of the second semiconductor layer 930 in the first region 110 is lower than a second upper surface of the second semiconductor layer 930 in a second region 120.

Referring to FIG. 10 and FIG. 11C, method 1000 can proceed to operation 1030, in which a semiconductor material of the second semiconductor layer 930 can be grown in the first region 110, such that the first upper surface of the second semiconductor layer 930 in the first region 110 is flush with an upper surface of the insulating layer 940. In some implementations, an epitaxial growth process and a followed CMP process can be performed in operation 1030.

Referring to FIG. 10 and FIG. 11D, method 1000 can proceed to operation 1040, in which a first semiconductor layer 950 can be bonded to the insulating layer 940 and the second semiconductor layer 930, and the first semiconductor layer 950 can be thinned. As shown in FIG. 11D, the first semiconductor layer 950 (i.e., active layer) can be bonded to the insulating layer 940 and the second semiconductor layer 930 by any suitable bonding method described above. After the bonding, the first semiconductor layer 950 (i.e., active layer) can be thinned to achieve the desired thickness. In some implementations, the first semiconductor layer 950 can be thinned by performing a CMP process.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations, but should be defined only in accordance with the following claims and their equivalents.

What is claimed is:

1. A semiconductor structure, comprising:
a lower semiconductor layer;
an upper semiconductor layer; and
an insulating layer between the lower semiconductor layer and the upper semiconductor layer,
wherein a first thickness of the upper semiconductor layer in a first region is greater than a second thickness of the upper semiconductor layer in a second region.

2. The semiconductor structure of claim 1, wherein:
the lower semiconductor layer and the upper semiconductor layer comprise silicon; and
the insulating layer comprises silicon oxide.

3. The semiconductor structure of claim 1, wherein:
the insulating layer extends in the first region and the second region; and
the lower semiconductor layer is separated from the upper semiconductor layer comprising silicon by the insulating layer.

4. The semiconductor structure of claim 3, wherein:
a first upper surface of the upper semiconductor layer in the first region is higher than a second upper surface of the upper semiconductor layer in the second region.

5. The semiconductor structure of claim 1, wherein:
the insulating layer extends in the second region without in the first region; and
the lower semiconductor layer is in contact with the upper semiconductor layer comprising silicon in the first region.

6. The semiconductor structure of claim 5, wherein:
the upper semiconductor layer has a flush upper surface.

7. The semiconductor structure of claim 1, wherein:
a thickness of the insulating layer is in a range between 10 nm and 30 nm.

8. The semiconductor structure of claim 1, further comprising:
a first group of transistors having a first operating voltage and formed in the upper semiconductor layer in the first region; and
a second group of transistors having a second operating voltage lower than the first operating voltage and formed in the upper semiconductor layer in the second region.

9. The semiconductor structure of claim 1, wherein a first material of the upper semiconductor layer is different from a second material of the lower semiconductor layer.

10. The semiconductor structure of claim 1, wherein a first material of the upper semiconductor layer is same as a second material of the lower semiconductor layer.

11. A semiconductor structure, comprising:
a lower semiconductor layer;
an upper semiconductor layer; and
an insulating layer between the lower semiconductor layer and the upper semiconductor layer,
wherein a first thickness of the insulating layer in a first region is greater than a second thickness of the insulating layer in a second region.

12. The semiconductor structure of claim 11, wherein:
the lower semiconductor layer and the upper semiconductor layer comprise silicon; and
the insulating layer comprises silicon oxide.

13. The semiconductor structure of claim 11, wherein:
the insulating layer has a flush upper surface; and
a first lower surface of the insulating layer in the first region is lower than a second lower surface of the insulating layer in the second region.

14. The semiconductor structure of claim 11, wherein:
the upper semiconductor layer has a flush upper surface; and
a first upper surface of the lower semiconductor layer in the first region is lower than a second upper surface of the lower semiconductor layer in the second region.

15. The semiconductor structure of claim 11, further comprising:
a first group of transistors having a first operating voltage and formed in the upper semiconductor layer in the first region; and
a second group of transistors having a second operating voltage lower than the first operating voltage and formed in the upper semiconductor layer in the second region.

16. The semiconductor structure of claim 11, wherein a first material of the upper semiconductor layer is different from a second material of the lower semiconductor layer.

17. The semiconductor structure of claim 11, wherein a first material of the upper semiconductor layer is same as a second material of the lower semiconductor layer.

18. A method of forming a semiconductor structure, comprising:
removing a portion of a first semiconductor layer in a second region, such that a first upper surface of the first semiconductor layer in a first region is higher than a second upper surface of the first semiconductor layer in the second region;
forming an insulating layer on a second semiconductor layer;
bonding the first semiconductor layer to the insulating layer; and
thinning the first semiconductor layer, such that a first thickness of the first semiconductor layer in the first region is greater than a second thickness of the first semiconductor layer in the second region.

19. The method of claim 18, wherein bonding the first semiconductor layer to the insulating layer comprises:
bonding a flush lower surface of the first semiconductor layer to a flush upper surface of the insulating layer.

20. The method of claim 18, wherein forming the insulating layer on the second semiconductor layer comprises:
oxidizing an upper surface of the second semiconductor layer to form the insulating layer.
